(19) United States
(12) Patent Application Publication
(10) Pub. No.: US 2009/0015146 A1
(43) Pub. Date: Jan. 15, 2009

(54) ORGANIC EL DISPLAY DEVICE

(75) Inventors: Masahiro TANAKA, Chiba (JP); Toshiyuki MATSUURA, Mobara (JP); Sukekazu ARATANI, Hitachiota (JP); Masao SHIMIZU, Hitachi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi Display, Ltd.

(21) Appl. No.: 12/037,960

(22) Filed: Feb. 27, 2008

(30) Foreign Application Priority Data
Feb. 28, 2007 (JP) 2007-049658

(51) Int. Cl. H01J 1/62

(52) U.S. Cl. 313/504

(57) ABSTRACT

The present invention provides a top-emission-type organic EL display device, that is, an organic EL display device which can suppress changes of a threshold voltage and a light emitting start voltage, and the generation of brightness irregularities. The organic EL display device includes lower electrodes arranged on a main surface of an element substrate, a multi-layered organic EL layer arranged on the lower electrodes, and a light transmitting upper electrode arranged on the organic EL layer. A layer in contact with the lower electrode of the organic EL layer forms a hole injection layer constituted of a V₂O₅ layer.

### CROSS-REFERENCE TO RELATED APPLICATIONS

The disclosure of Japanese Patent Application No. 2007-049658 filed on 2007 Feb. 28 (yyyy/mm/dd) including the claims, the specification, the drawings and the abstract is incorporated herein by reference in its entirety.

### BACKGROUND OF THE INVENTION

1. Field of the Invention

The present invention relates to an organic EL display device, and more particularly to an organic EL display device which includes top-emission-type organic EL light-emitting elements.

2. Description of Related Art

The organic EL display device is classified into a so-called bottom-emission-type organic EL display device and a so-called top-emission-type organic EL display device. In the bottom-emission-type organic EL display device, on a main surface of an insulation substrate preferably formed of a glass substrate which constitutes a TFT substrate, organic EL elements are formed, and each organic EL element is constituted of a light emitting mechanism formed by sequentially stacking a transparent electrode (made of ITO or the like) which constitutes a first electrode or one electrode, a multi-layered organic film which emits light with applying of an electric field thereto (also referred to as an organic light emitting layer), and a metal electrode having reflection property which constitutes a second electrode or another electrode. A large number of organic EL elements are arranged on the insulation substrate in a matrix array. Another substrate or a sealing film referred to as a sealing can is provided to cover the stacked structure for shielding the above-mentioned light emitting structure from an external atmosphere. Further, for example, using the transparent electrode constituting one electrode as an anode and a metal electrode constituting another electrode as a cathode electrode, an electric field is applied between both electrodes so as to inject carriers (electrons and holes) into the organic multi-layered film thus allowing the organic multi-layered film to emit light. The emitted light is radiated to the outside from a glass substrate side.

On the other hand, the top-emission-type organic EL display device is configured such that the above-mentioned one electrode is formed of a metal electrode having reflection property and the above-mentioned another electrode is formed of a transparent electrode made of ITO or the like, an electric field is applied between both electrodes to allow the light emitting layer to emit light, and the emitted light is radiated from another electrode side. In the top-emission-type organic EL display device, an area above a drive circuit formed on the insulation substrate can be also used as a light emitting area. Further, the top-emission-type organic EL display device can use a transparent plate preferably formed of a glass plate as a member corresponding to the sealing can of the bottom-emission-type organic EL display device.

As exemplified in FIG. 5, this type of organic EL display device is configured to seal a sealing substrate 81 and an element substrate 82 using a sealing member 83. Here, FIG. 5 schematically shows a cross section of one example of the organic EL display device as viewed in the direction parallel to the light radiation direction.

In the constitution of the organic EL display device shown in FIG. 5, a trench 81a is formed in an inner surface of the sealing substrate 81 facing the element substrate 82 in an opposed manner, and a desiccant assembly 84 is fixed in the inside of the trench 81a. The desiccant assembly 84 is, for example, formed of a desiccant 86 made of CaO (calcium oxide), Sr (strontium) or the like and a bonding material 87 such as an adhesive agent, for example, and the desiccant assembly 84 is fixedly mounted on the sealing substrate 81 using the bonding material 87. The desiccant assembly 84 and the bonding material 87 are transparent.

On the other hand, on a main surface of the element substrate 82, that is, on a surface of the element substrate 82 facing the sealing substrate 81 and forming TFT elements and the like not shown in the drawing thereon, a light emitting element portion 85 is arranged. The light emitting element portion 85 is constituted by sequentially stacking a lower electrode 88 formed of a metal film having reflection property, an organic multi-layered film 89 having a light emitting layer and a transparent upper electrode 90 in this order from an element substrate 82 side.

In such a constitution, the desiccant assembly 84 is assembled in the element substrate 82 for preventing lowering of performance of the organic multi-layered film 89 attributed to the absorption of water.

With respect to this kind of organic EL display device, patent document 1 (JP-A-2005-32618) discloses a top-emission-type organic EL light emitting element which arranges a hole injection layer being in contact with a transparent upper electrode and including inorganic materials formed of a transition-metal oxide such as a vanadium oxide. Further, patent document 2 (JP-A-9-63771) discloses a bottom-emission-type organic EL light emitting element which uses a lower electrode made of an ITO as an anode and an electrode having reflection property as an upper electrode.

### SUMMARY OF THE INVENTION

In such a top-emission-type organic EL display device, there has been proposed the constitution which uses the upper electrode as a cathode and the lower electrode as an anode, Al (aluminum) having a high reflection coefficient as the lower electrode, and stacks an ITO film or an IZO film having a high work function on the Al film.

With such a constitution, however, the restriction is imposed on the separation of pixels due to low insulating property of the ITO film or the IZO film. To cope with such restriction, an organic EL layer or an upper electrode having the multi-layered stacked structure has been provided. However, during manufacturing steps of the organic EL layer or the upper electrode, foreign materials are absorbed in films including the above-mentioned ITO film or IZO film or these films are contaminated with the foreign materials thus giving rise to the fluctuation of a threshold voltage or a light emitting start voltage, the generation of brightness irregularities or the like attributed to these absorption of the foreign materials in the films or the contamination of films by the foreign materials. Accordingly, there has been a demand for ideas which can cope with such drawbacks.

It is an object of the present invention to provide an organic EL display device which can overcome the above-mentioned drawbacks and can acquire a stable threshold voltage and a stable light emitting start voltage for a long period, and has an excellent light emitting property without generating brightness irregularities.

To achieve the above-mentioned object, the present invention is directed to a top-emission-type organic EL display device configured as follows. A lower electrode is made of Al or Al alloy, a hole injection layer formed of a V₂O₅ layer is stacked on the lower electrode, a multi-layered organic EL layer such as a hole transport layer is arranged on the hole injection layer formed of the V₂O₅ layer, and a light-transmitting upper electrode constituting a cathode electrode is further stacked on the organic EL layer.

By stacking the hole injection layer formed of the V₂O₅ layer on the lower electrode in a state that the hole injection layer is in contact with the lower electrode made of Al or Al alloy and constituting the anode, the present invention can obtain following advantageous effects.

(1) All of the V₂O₅ layer, the organic layer, the electron injection layer and the upper electrode can be formed in vacuum consecutively and hence, bonding portions of the respective layers can be held in a clean state, and the number of interface ions or the like which move due to the application of voltage is small and hence, a change of a threshold value is also small.

(2) A threshold voltage and a light emitting start voltage can be held stable for a long period thus providing an organic EL display device exhibiting excellent light emitting property and having a prolonged lifetime.

(3) The generation of brightness irregularities can be suppressed effectively.

(4) The lowering of light reflection property of the lower electrode can be suppressed effectively.

### BRIEF DESCRIPTION OF THE DRAWINGS

FIG. 1 is a schematic cross-sectional view for explaining the schematic structure of one embodiment of an organic EL display device according to the present invention;

FIG. 2 is a schematic cross-sectional view of a light emitting element side of the organic EL display device in FIG. 1;

FIG. 3 is a schematic enlarged cross-sectional view of an organic EL layer;

FIG. 4 is a schematic cross-sectional view for explaining another embodiment of an organic EL display device according to the present invention; and

FIG. 5 is a schematic cross-sectional view for explaining schematic structure of a conventional organic EL display device.

### DETAILED DESCRIPTION OF THE INVENTION

Hereinafter, preferred embodiments of the present invention are explained in detail in conjunction with drawings showing these embodiments.

### Embodiment 1

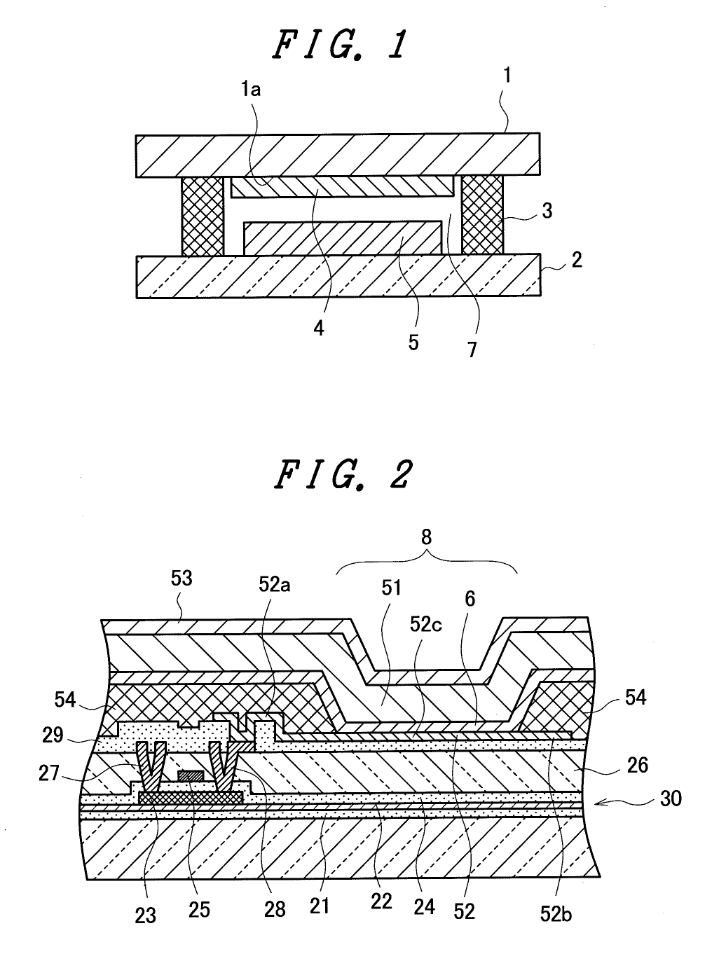

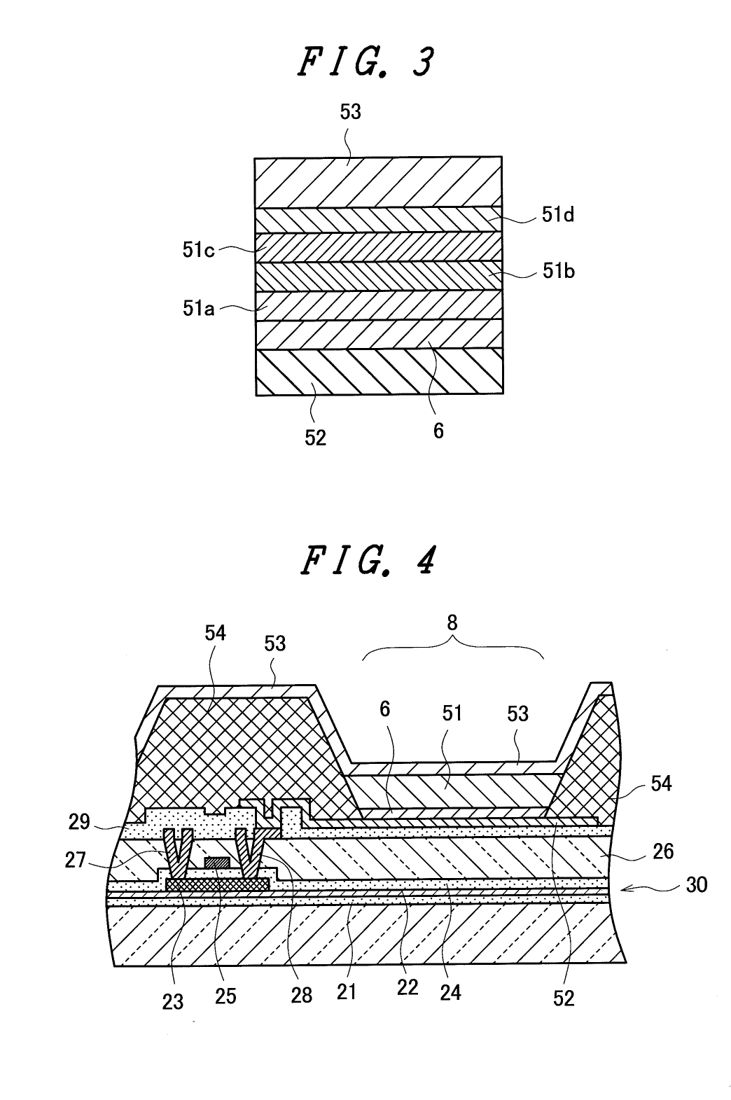

FIG. 1 to FIG. 3 are schematic views for explaining the schematic structure of one embodiment of an organic EL display device according to the present invention. FIG. 1 is a cross-sectional view of the organic EL display device as viewed in the direction parallel to the light radiation direction, FIG. 2 is a cross-sectional view of an element substrate shown in FIG. 1, and FIG. 3 is an enlarged cross-sectional view of an organic EL layer. In FIG. 1 to FIG. 3, numeral 1 indicates a sealing substrate, numeral 2 indicates an element substrate, numeral 3 indicates a sealing member, numeral 4 indicates a desiccant, numeral 5 indicates a light emitting element portion, numeral 51 indicates an organic EL layer, numeral 52 indicates lower electrodes having reflection property, numeral 53 indicates an upper electrode having light transmitting property, numeral 54 indicates projecting banks, numeral 6 indicates a V₂O₅ layer, and numeral 7 indicates a sealing space.

The sealing substrate 1 is, for example, formed of a glass substrate having light transmitting property. To be more specific, the sealing substrate 1 is bonded to the element substrate 2 described later by way of the sealing material 3 to define a region surrounded by both substrates 1, 2 and the sealing material 3, that is, a sealing space 7. The sealing substrate 1 is configured to hold the transparent desiccant 4 on an inner surface 1a thereof and to absorb moisture in the inside of the sealing space 7. Further, the element substrate 2 bonded to the sealing substrate 1 forms the light emitting element portion 5 on a portion thereof facing the sealing substrate 1 in an opposed manner.

FIG. 2 shows one example of the organic EL display device in detail. The element substrate 2 is a substrate which forms a silicon nitride SiN film 21 and a silicon oxide SiO₂ film 22 on a main surface thereof and is preferably formed of a transparent glass. The element substrate 2 constitutes a TFT substrate. Semiconductor films 23 are formed in switching element regions arranged on the silicon oxide SiO₂ film 22 by patterning. A gate insulation film 24 is formed on the semiconductor films 23 so as to cover the semiconductor films 23. Gates 25 are formed on the gate insulation film 24 by patterning. A leveling film 26 having insulating property is formed on the gates 25 so as to cover the gates 25. Lines 27 are constituted of various lines between switching elements (lines between switches, signal lines, drain lines) constituting drain electrodes of the switching elements. Lines 28 are shield members which are also used as lines between the switching elements (shield members also being used as the lines between the switches) constituting source electrodes. The lines 27 and the lines 28 are connected to the semiconductor films 23 via contact holes which run through the leveling film 26 and the gate insulation film 24. An insulation film 29 is formed to cover the lines 27 between the switches and the shield members 28 which are also used as the lines between the switches. Numeral 30 indicates the TFT substrate.

The lower electrodes 52, the V₂O₅ layer 6, the multi-layered organic EL film 51 including the V₂O₅ layer 6, the upper electrode 53, and the projecting banks 54 for separating pixels are respectively arranged on the TFT substrate 30.

First of all, the planar lower electrode 52 made of Al or Al alloy which constitutes a pixel electrode has one end 52a thereof connected to the shield member 28 which is also used as the line between the switches via the contact hole formed in the insulation film 29 and has another end 52b thereof extended to and arranged on a neighboring TFT element (not shown in the drawing) side. The lower electrode 52 constitutes a portion of the light emitting element portion 5 and functions as an anode.

The projecting bank 54 is stacked to cover a portion of the lower electrode 52. The bank 54 is, for example, made of an inorganic insulation material such as silicon oxide or silicon nitride and is arranged to cover distal end portions of one end 52a and another end 52b except for a center portion 52c of the lower electrode 52. A light emitting portion defined by the banks 54 and corresponding to the center portion 52c of the lower electrode 52 forms the light emitting areas 8. The light emitting areas 8 are separated from each other by the banks 54.

On the other hand, the V₂O₅ layer 6 is arranged to cover the center portion 52c of the lower electrode 52 defined by the banks 54 and having a surface thereof exposed. The V₂O₅ layer 6 is arranged in common on neighboring pixel units (not shown in the drawing) after getting over the banks 54.

The V₂O₅ layer 6 can be formed by vapor deposition and has a thickness of 1 nm to 30 nm in practical use. The thickness is more preferably set to a value which falls within a range from 5 nm to 10 nm. When the thickness of the V₂O₅ layer 6 is less than nm, there exists a possibility that the lower electrode does not function as the anode, while when the thickness of the V₂O₅ layer 6 exceeds 30 nm, there exists a possibility that the reflection property and the conductivity of the V₂O₅ layer 6 are lowered.

Further, in the constitution which applies the V₂O₅ layer 6 to the lower electrode 52 made of Al or Al alloy, a threshold voltage tends to become slightly high by an amount corresponding to difference in work function between A₁ and V₂O₅. However, a change of the threshold voltage with time is small and hence, the constitution eventually facilitates a control of the organic EL display device.

In this embodiment, the organic EL layer 51 which covers the V₂O₅ layer 6 and forms the hole injection layer using the V₂O₅ layer 6, and the light-transmitting upper electrode 53 formed of an IZO film and constituting the common electrode are stacked to each other. The upper electrode 53 functions as a cathode.

Here, the formation of the V₂O₅ layer 6, the organic EL layer 51 and the upper electrode 53 can be performed in vacuum consecutively without exposing these layers to atmosphere.

Due to the consecutive formation of these layers, not to mention the avoidance of adhesion of foreign materials, since the interface is not contaminated, the elevation of a light-emitting start voltage can be obviated thus contributing to the prolongation of lifetime.

One example of the organic EL layer 51 which adopts V₂O₅ layer 6 as the hole injection layer is shown in detail in FIG. 3. In the organic EL layer 51 shown in FIG. 3, the V₂O₅ layer 6 is arranged in contact with the lower electrode 52 as the hole injection layer, and a hole transport layer 51a, a light emitting layer 51b, an electron transport layer 51c, and an electron injection layer 51d are respectively stacked on the V₂O₅ layer 6 sequentially, and the upper electrode 53 which constitutes the common electrode is formed as an uppermost layer.

In the above-mentioned constitution, the upper electrode 53 functions as a cathode having light transmitting property, while the lower electrode 52 of the pixel electrode functions as an anode having reflection property.

Although the upper electrode 53 functions as the cathode having light transmitting property, the upper electrode 53 may be made of other transparent conductive material in place of the above-mentioned IZO. Further, the upper electrode 53 may preferably be made of a material having low light reflectance for suppressing reflection of light radiated from the light emitting layer.

On the other hand, the lower electrode 52, for enhancing properties thereof, may be formed using Al alloy such as Al/Nd alloy or Al/Si alloy, for example, in stead of using Al in a single form. Further, the lower electrode 52 may be formed using other metal having high reflection property.

The light emitting layer 51b may be formed using a material which emits light of desired color when a predetermined voltage is applied between the transparent upper electrode 53 constituting the cathode and the lower electrode 52 constituting the anode.

To explain materials of the light emitting layers 51b, for example, the light emitting layer may adopt a material formed by dispersing DCM-1 (4-(dicyanomethylene)-2-methyl-6-(p-dimethylamino-styryl-4H-pyran) in Alq3 (tris(8-quinolinolate)aluminum) for emitting red light, the light emitting layer may adopt Alq3, Bebq, or Alq3 doped with quinacridone for emitting green light, for example, and the light emitting layer may adopt DPVBi(4,4′-bis(2,2-diphenylvinyl)biphenyl), a material formed of DPVBi(4,4′-bis(2,2-diphenyl vinyl)biphenyl) and BCzVBi (4,4′-bis(2-carbazole vinylene)biphenyl) or a material doped with di-styryl arylene derivative as a host and di-styryl amine derivative as a guest for emitting blue light, for example.

Further, in the respective light emitting layers 51b, the hole transport layer 51a may be formed using α-NPD (N,N-di(α-naphthyl)-N,N-diphenyl 1,1′-biphenyl-4,4′-diamine), or triphenyl diamine derivative TPD (N,N′-bis(3-methyl phenyl) 1,1′-biphenyl-4,4′-diamine). The electron transport layer 51c may be formed using Alq3. Further, polymer materials may be used for forming the respective light emitting layers in place of the above-mentioned low-molecular materials.

In the organic EL element with the organic EL layer 51 having such a constitution, a DC power source is connected to the lower electrode 52 constituting the anode and the upper electrode 53 constituting the cathode and, when a DC voltage is applied between both electrodes, holes injected from the lower electrode 52 and electrons injected from the upper electrode 53 respectively arrive at the light emitting layer, and the recoupling of electrons and holes is generated thus generating the emission of light having a predetermined wavelength.

### Embodiment 2

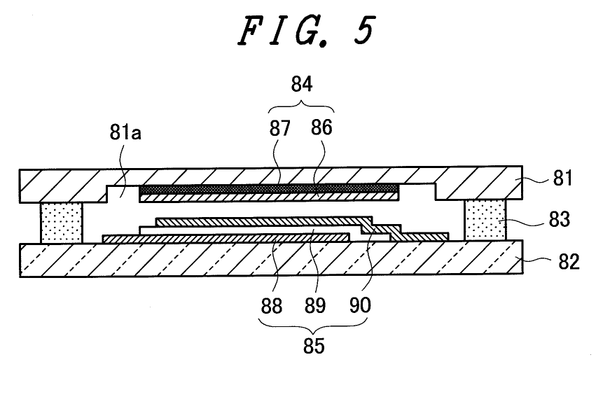

FIG. 4 is a schematic cross-sectional view of light emitting element side for explaining the schematic structure of another embodiment of the organic EL display device according to the present invention, wherein parts identical with the parts in the above-mentioned drawings are given the same symbols. The embodiment 2 shown in FIG. 4 is characterized by the constitution which defines an organic EL layer 51 including a V₂O₅ layer 6 for every pixel unit using banks 54. Other constitutions are equal to the corresponding constitutions shown in FIG. 1 to FIG. 3.

What is claimed is:

1. An organic EL display device comprising:
lower electrodes made of aluminum or aluminum alloy and arranged on a main surface of an element substrate;
an organic EL layer having the multi-layered structure and arranged on the lower electrodes, the multi-layered organic EL layer having a hole injection layer being in contact with the lower electrodes and formed of a V₂O₅ layer;
a light-transmitting upper electrode arranged over the organic EL layer; and
a sealing substrate arranged to face the element substrate in an opposed manner; wherein
light is emitted from an upper electrode side.

2. An organic EL display device according to claim 1, wherein a thickness of the V₂O₅ layer is set to a value ranging from 1 nm to 30 nm.

3. An organic EL display device according to claim 1, wherein the organic EL layer is configured such that a hole transport layer, a light emitting layer, an electron transport layer, and an electron injection layer are sequentially stacked on the hole injection layer.

4. An organic EL display device according to claim 1, wherein the lower electrodes constitute anodes, and the upper electrode constitutes a cathode.

5. An organic EL display device according to claim 1, wherein the lower electrodes are separated from each other for every pixel.

6. An organic EL display device according to claim 1, wherein the organic EL layer includes the light emitting layers, and the light emitting layers are separated from each other on an insulation film which insulates pixel electrodes from each other.
